(19) United States
(12) Patent Application Publication
(10) Pub. No.: US 2008/0143396 A1
(43) Pub. Date: Jun. 19, 2008

(54) Semiconductor device

(75) Inventor: Ryuji Nishida, Kanagawa (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/000,361

(22) Filed: Dec. 12, 2007

(30) Foreign Application Priority Data
Dec. 13, 2006 (JP) JP2006-335336

(51) Int. Cl. H03L 7/06

(52) U.S. Cl. 327/146

(57) ABSTRACT

A data signal is generated in a pattern generation logic built in a TX port and given to a serializer, and a path is provided for looping an output of the serializer back to a deserializer and a CDR circuit of an RX port, whereby a BIST configuration enabling jitter measurement inside a high-speed serial transmission input/output section is adopted.

### BACKGROUND OF THE INVENTION

1. Field of the Invention

The present invention relates to a semiconductor device, and particularly relates to a semiconductor device having a high-speed serial transmission input/output section with a jitter measuring circuit built therein.

2. Description of the Background Art

There has recently been an increase in semiconductor chips loaded with high-speed serial transmission input/output sections of a variety of specifications, such as PCI Express, SATA-2, and GIGA bit Ethernet (registered trademarks). This is attributed to that a skew of the top of a system board has become relatively large in a conventional parallel bus transmission system associated with speeding-up of transmission among chips of the system and hence an attempt of speeding-up has come to be impossible.

For realizing high-speed serial transmission, it is necessary to provide in the high-speed serial transmission input/output section a serializer that converts parallel data into serial data and a deserializer that converts serial data into parallel data.

As one example of such a configuration having the serializer and the deserializer, a configuration shown in FIG. 3 of Japanese Patent Application Laid-Open No 2006-250824 is cited.

As thus described, in a semiconductor chip provided with a high-speed serial transmission input/output section having the serializer and the deserializer is operated at high speed of several Gbps. For determining an output timing of serial data, an I/O characteristic in the high-speed serial transmission input/output section depends upon a jitter of a high-speed clock given to the serializer and a jitter of the high-speed clock generated based upon a timing of an edge detected from a data row of inputted serial data. It is therefore important for ensuring a normal system operation to hold within specification a jitter characteristic having a configuration to generate these high-speed clocks.

However, in the foregoing configuration to generate a high-speed clock, a jitter characteristic not satisfying the specification might be generated due to product variation in manufacturing, and it is thereby necessary to reliably detect a semiconductor chip having such a characteristic before shipment so as to prevent the chip from being shipped.

The jitter characteristic defined by the specification is in a psec (pico-second) order, and therefore, while a highly accurate detection method is desired, manufacturing cost as well as test cost of the high-speed serial transmission input/output section needs to be suppressed since being also loaded on a semiconductor chip intended for consumer equipment.

It is to be noted that, although Japanese Patent Laid-Open Application No. 2006-250824 shows a transmission block having the serializer and the deserializer and a reception block having the serializer and the deserializer, disclosing a configuration where a data analysis section is provided in the reception block to detect error data, however, the foregoing jitter of a high-speed clock is not considered.

An output signal of the high-speed serial transmission input/output section has hitherto been directly measured using high-performance jitter measuring equipment outside to measure a jitter. However, a wafer is typically probed to be measured in a wafer condition test (wafer test), where a large noise is generated at a contact point or in probing, and it has thus been difficult to measure a jitter characteristic with high accuracy. Hence there has been a problem in that a defective product cannot be detected in the wafer test and when detected in a test after assembly, cost increases just by an amount of cost for assembly.

Further, also in the test after assembly, a jitter cannot be measured with high accuracy with a tester having performance currently distributed in a mass production test. Therefore, another high-performance jitter measuring equipment is required, which leads to an increase in test cost.

Moreover, in the case of directly measuring an output signal of the high-speed serial transmission input/output section, the output signal needs to be measured by probing. However, probing is difficult for example with the section in the state of being mounted on a system board, and measurement is thus not possible.

### SUMMARY OF THE INVENTION

There is provided a semiconductor device, which includes a high-speed serial transmission input/output section having a serializer and a deserializer, wherein a jitter characteristic of a high-speed clock can be measured with high accuracy without the use of high-performance jitter measuring equipment.

An aspect of the semiconductor device according to the present invention is that during the time of jitter measuring test, a data signal is generated in a pattern generation logic built in a TX port and given to a serializer, and a path is provided for looping an output of the serializer back to a deserializer and a CDR circuit of an RX port, whereby a BIST configuration enabling jitter measurement inside a high-speed serial transmission input/output section is adopted.

According to the above semiconductor device, there is no need for probing a wafer for measurement in a wafer test, thereby enabling measurement of a jitter characteristic with high accuracy, and reliable detection of a defective product in the wafer test. Therefore, it is possible to prevent a defective product from being packed, so as to reduce assembly cost. Further, adoption of the BIST configuration allows a closed test to be performed inside the semiconductor chip.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram for explaining a configuration of a high-speed serial transmission input/output section as a prerequisite technique of the present invention;

FIG. 2 is a timing chart schematically showing a clock reproducing operation in a CDR circuit;

FIG. 3 is a block diagram showing a configuration of an input section of a deserializer;

FIG. 4 is a block diagram for explaining a configuration of a main part of a high-speed serial transmission input/output section in Embodiment 1 according to the present invention;

FIG. 5 is a block diagram for explaining an entire configuration of the high-speed serial transmission input/output section in Embodiment 1 according to the present invention;

FIG. 6 is a block diagram showing a configuration of an input section of a deserializer:

FIG. 7 shows a block diagram of a configuration of a variable delay element;

FIG. 8 is a timing chart schematically showing an operation to make a test pattern captured in the deserializer;

FIG. 9 is a timing chart schematically showing an operation to make a test pattern captured in the deserializer;

FIG. 10 is a flowchart showing an operation of a jitter measurement test;

FIG. 11 is a view showing a jitter measurement result;

FIG. 12 is a block diagram for explaining a configuration of Modified Example 1 of Embodiment 1 according to the present invention;

FIG. 13 is a block diagram for explaining a configuration of Modified Example 2 of Embodiment 1 according to the present invention;

FIG. 14 is a block diagram for explaining a configuration of a main part of a high-speed serial transmission input/output section in Embodiment 2 of the present invention;

FIG. 15 is a block diagram showing a configuration of a CDR circuit;

FIG. 16 is a timing chart for explaining an operation in a CDR circuit to generate a high-speed clock with its phase shifted by 90 degrees with respect to a test pattern;

FIG. 17 is a timing chart for explaining an operation in a CDR circuit to delay a high-speed clock with its phase shifted by 90 degrees with respect to a test pattern; and

FIG. 18 is a timing chart for explaining an operation in a CDR circuit to advance a high-speed clock with its phase shifted by 90 degrees with respect to a test pattern.

### DESCRIPTION OF THE PREFERRED EMBODIMENTS

### <Prerequisite Technique>

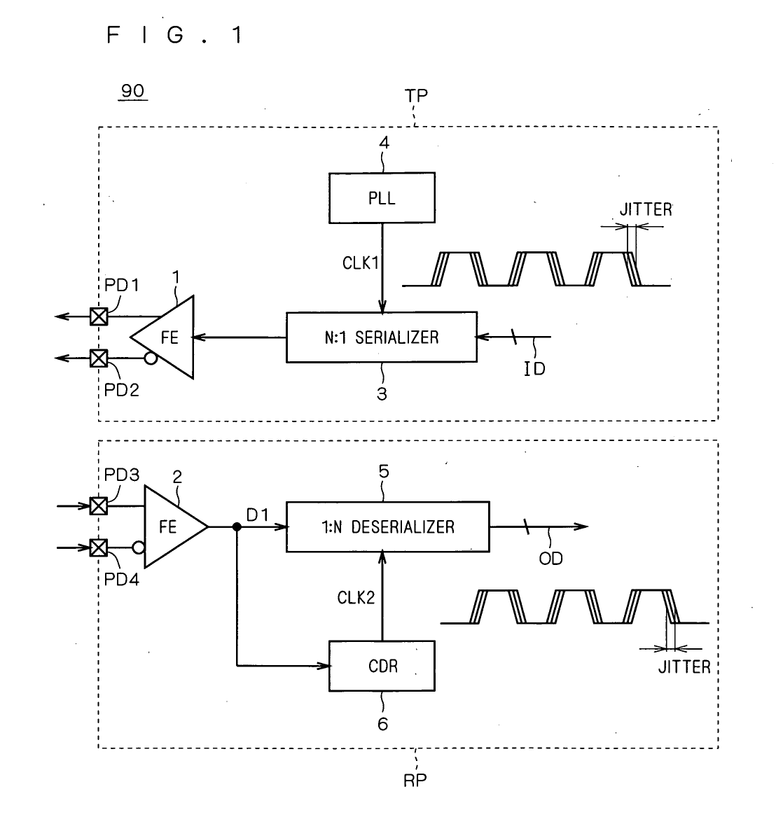

In advance of description of an embodiment of the present invention, a basic configuration and operation of a high-speed serial transmission input/output section having a serializer and a deserializer is described as a prerequisite technique with reference to FIGS. 1 to 3.

FIG. 1 is a block diagram showing a basic configuration of a typical high-speed serial transmission input/output section 90. As shown in FIG. 1, the high-speed serial transmission input/output section 90 takes a full duplex configuration. An output side is called a TX port TP, and an input side is called an RX port RP.

The TX port TP includes: a PLL (Phase Locked Loop) circuit 4 (first clock generating section) which generates a high-speed clock CLK1 (first clock); a serializer 3 which, upon receipt of the high-speed clock CLK1 outputted from the PLL circuit 4, converts N-bit input data ID as parallel data into serial data and outputs the converted data at a timing of startup of the high-speed clock CLK1; and an output buffer 1 (output section) which receives data outputted from the serializer 3.

It is to be noted that the output buffer 1 is a differential buffer, and a noninverted output and an inverted output are respectively connected to pads PD1 and PD2 (first terminal section).

The RX port RP includes: an input buffer 2 (input section); a CDR (Clock Data Recovery) circuit 6 which, upon receipt of data D1 outputted from the input buffer 2, reproduces and outputs the high-speed clock CLK1 as a high-speed clock CLK2 (second clock); and a deserializer 5 which converts data D1 as serial data into parallel data based upon the high-speed clock CLK2 generated in the CDR circuit 6 and outputs the converted data as the N-bit output data OD.

It is to be noted that the input buffer 2 is a differential buffer, and a noninverted input and an inverted input are respectively connected to pads PD3 and PD4.

In addition, FIG. 1 schematically shows that the high-speed clock CLK1 outputted from the PLL circuit 4 and the high-speed clock CLK2 outputted from the CDR circuit 6 have jitters.

The jitter of the high-speed clock CLK1 is outputted from the PLL circuit 4 through a flip-flop inside the serializer 3 and superposed as a jitter of serial data outputted from the serializer 3.

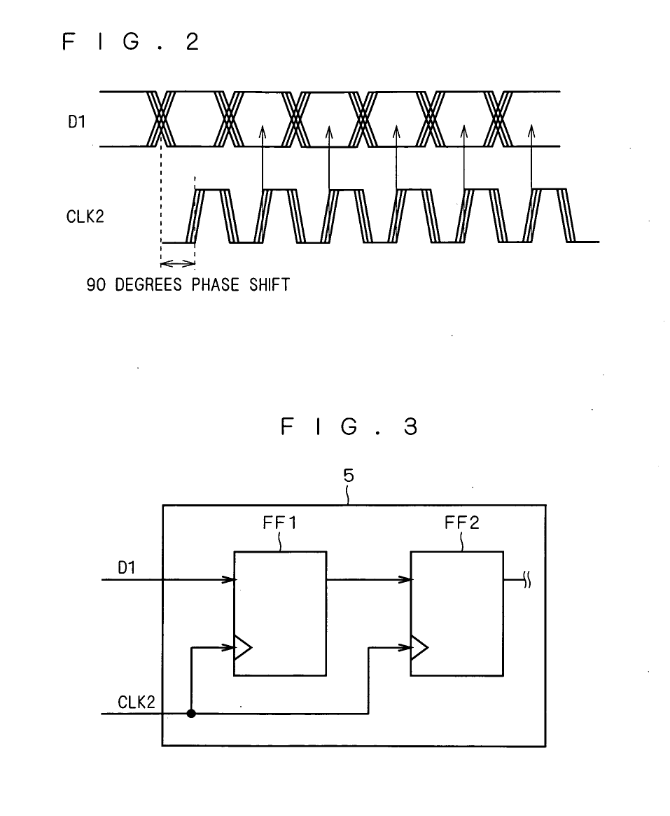

FIG. 2 is a view schematically showing a clock reproducing operation in the CDR circuit 6. The CDR circuit 6 detects an edge from a data row of the data D1, and generates the high-speed clock CLK2 whose phase is shifted by 90 degrees with the timing of the detected edge taken as a reference.

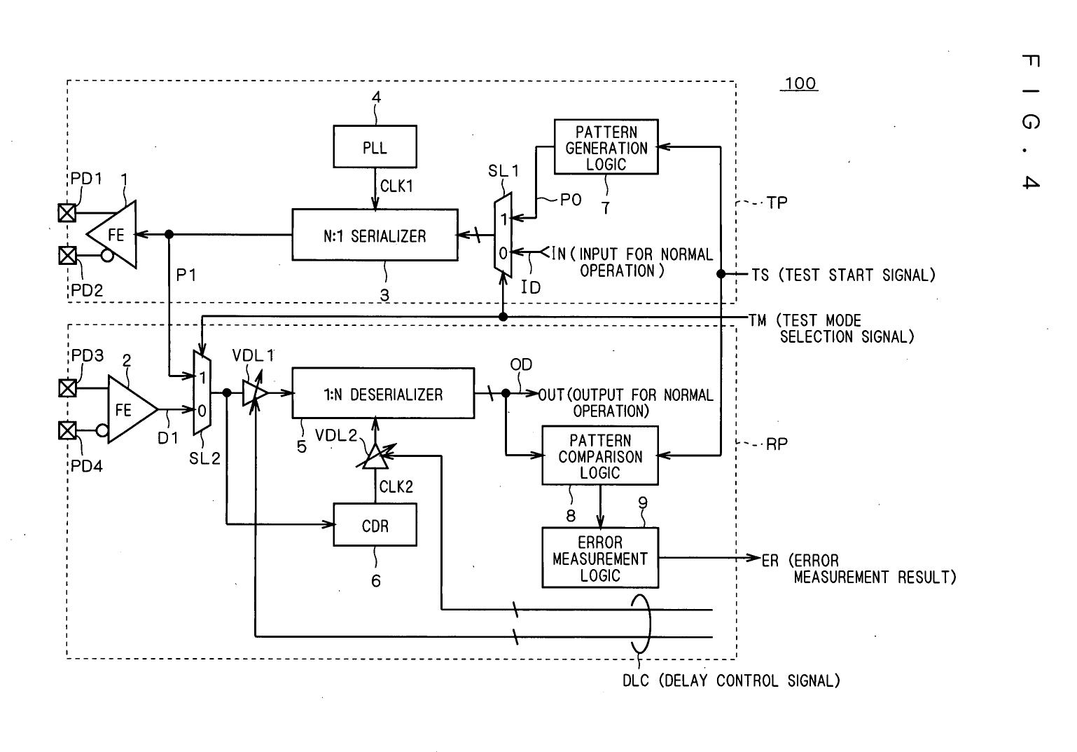

FIG. 3 is a block diagram showing a configuration of an input section of the deserializer 5. As shown in FIG. 3, in the input section of the deserializer 5, for example, a sift register having a flip-flops FF1 and FF2 is provided and input data can be captured by the sift register using the high-speed clock CLK2 so that data D1 can be captured at a point with the largest timing margin. Therefore, whether data can be captured normally depends upon the jitter characteristic of the high-speed clock CLK2 outputted by the CDR circuit 6.

Therefore, in a case where the jitter characteristics of the PLL circuit 4 and the CDR circuit 6 that generate the high-speed clocks CLK1 and CLK2 are out of specification, a normal system operation cannot be ensured, and a chip having the PLL circuit 4 and the CDR circuit 6 is thus handled as a defective product.

In the following, the high-speed serial transmission input/output section capable of detecting the jitter characteristics of the PLL circuit 4 and the CDR circuit 6 is described in Embodiments 1 and 2 according to the present invention.

### A. Embodiment 1

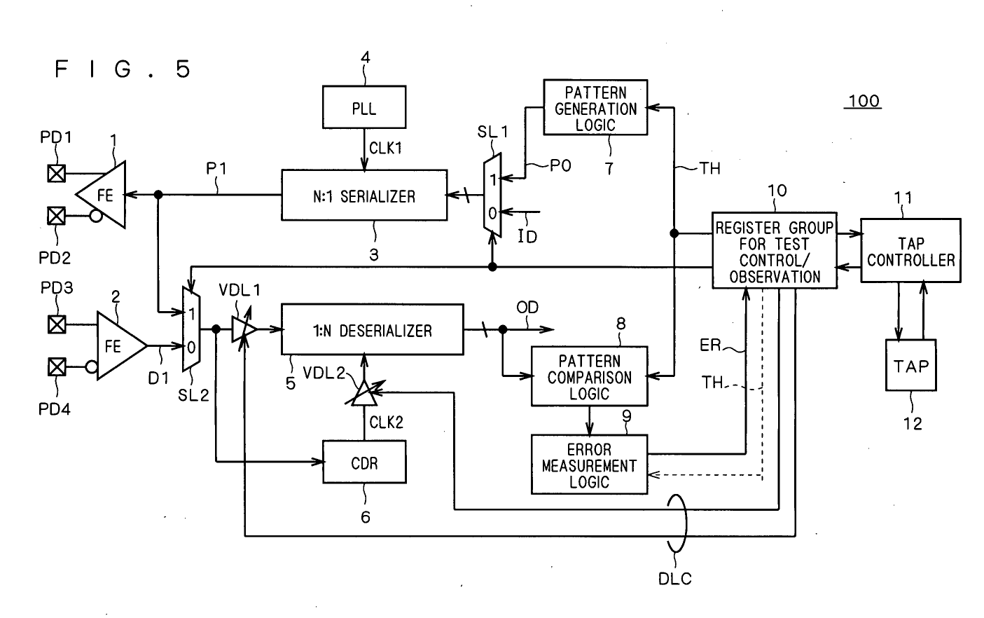

FIG. 4 is a block diagram showing a configuration of a main part of a high-speed serial transmission input/output section 100 in Embodiment 1 according to the present invention. It is to be noted that the same numerals/symbols are provided for the same configuration as that of the high-speed serial transmission input/output section 90 shown in FIG. 1, and an overlapping explanation is eliminated.

### A-1. Brief Summary of Device Configuration and Operation

First, a configuration and a schematic operation of the high-speed serial transmission input/output section 100 are described with reference to FIG. 4.

The high-speed serial transmission input/output section 100 has a jitter measurement test function, and the jitter measurement test function is activated upon receipt of a prescribed test start signal TS and test mode selection signal TM.

That is, at the time of the jitter measurement test, a data signal is generated in a pattern generation logic 7 built in the TX port TP and given to a serializer 3, and a path is provided for looping an output of the serializer 3 back to a deserializer 5 and the CDR circuit 6, whereby a BIST (Built In Self Test) configuration enabling jitter measurement inside the high-speed serial transmission input/output section 100 is adopted.

More specifically, at the time of the jitter measurement test, when a test start signal TS is given to the pattern generation logic 7 (pattern generating section) and a pattern comparison logic 8 (pattern comparing section) which are respectively built in the TX port TP and the RX port RP, an N-bit test pattern P0 (first pattern) is generated in the pattern generation logic 7 and then outputted. The test pattern P0 is given to the serializer 3 through a selector SL1.

The selector SL1 is switch-controlled by the test mode selection signal TM so as to give N-bit input data ID, inputted from the semiconductor chip side through an input for normal operation, to the serializer 3 at the time of the normal operation, and give the test pattern P0 to the serializer 3 at the time of the jitter measurement test. It is to be noted that in the following, a description of the normal operation is omitted, and only an operation at the time of the jitter measurement test is described.

The test pattern P0 given to the serializer 3 is converted into serial data and given as a test pattern P1 (second pattern) to the output buffer 1 and a selector SL2. The test pattern P1 given to the selector SL2 is given to a variable delay element VDL1 (first variable delay element) and the CDR circuit 6 through the selector SL2, and further given to the deserializer 5 through a variable delay element VDL2 (second variable delay element).

The selector SL2 is switch-controlled by the test mode selection signal TM so as to give the data D1, inputted into the high-speed serial transmission input/output section 100 from the outside of the semiconductor chip through pads PD3 and PD4, to the deserializer 5 at the time of the normal operation, and give the test pattern P1 converted into serial data to the deserializer 5 at the time of the jitter measurement test.

Upon receipt of the test pattern P1, the CDR circuit 6 generates the high-speed clock CLK2, and the high-speed clock CLK2 is given to the deserializer 5 through the variable delay element VDL1.

The variable delay elements VDL1 and VDL2 are delay elements capable of changing a delay time by a delay control signal DLC, and constitute a phase changing unit of arbitrarily changing a relative phase relation between the test pattern P1 and the high-speed clock CLK2 such that the elements are operated one by one to change the phase of the test pattern P1 or the high-speed clock CLK2.

Upon receipt of a test pattern whose phase has been changed or the high-speed clock CLK2 whose phase has been changed, the deserializer 5 converts the test pattern P1 into parallel data and outputted the data as the N-bit output data OD.

The output data OD is given to the semiconductor chip side through an output for normal operation as well as to the pattern comparison logic 8.

The pattern comparison logic 8 is activated upon receipt of the test start signal TS, and compares a pattern of the output data OD with a previously set pattern for comparison. Here, the pattern for comparison is equivalent to the test pattern P0 generated in the pattern generation logic 7. Output data OD with its pattern largely different from the pattern for comparison is determined as error data, and the comparison result information is given to an error measurement logic 9 (error measuring section).

In the error measurement logic 9, the comparison result information is held until stored in a predetermined amount, and subsequently outputted as an error measuring result ER.

### A-2. Jitter Measurement Test

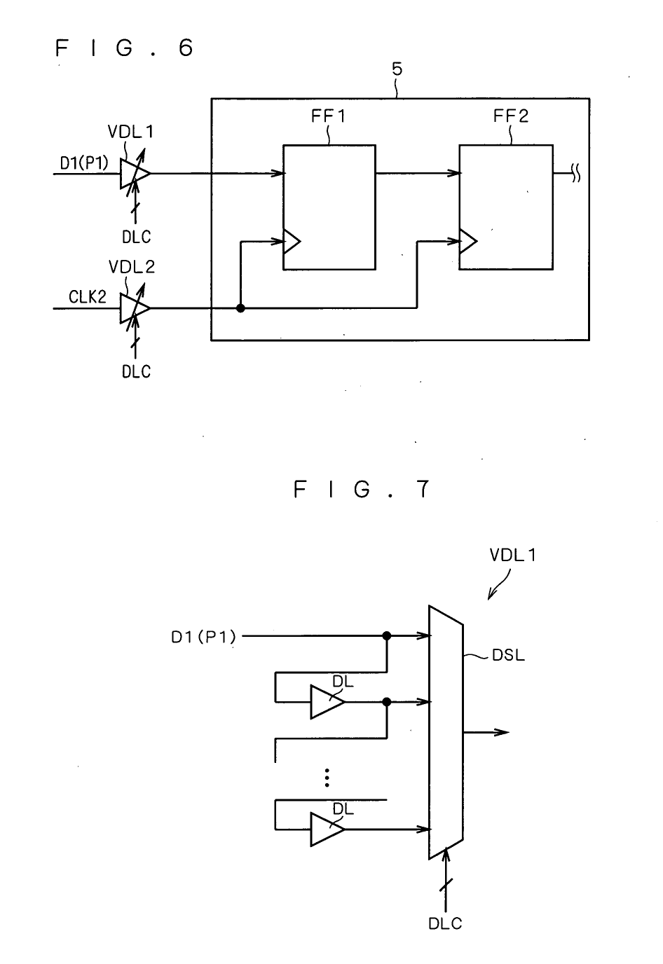

Next, a jitter measurement test in the high-speed serial transmission input/output section 100 is described with reference to FIGS. 5 to 11. It is to be noted that the high-speed serial transmission input/output section 100 shown in FIG. 5 shows an example where the delay control signal DLC, the test start signal TS and the test mode selection signal TM are generated in a register group 10 for test control/observation, and the register group 10 for test control/observation is configured to receive the error measuring result ER. Further, the register group 10 for test control/observation is configured to give and receive a signal to and from a TAP (Test Access Port) controller 11, and the TAP controller 11 is configured to give and receive a signal to and from the outside of the semiconductor chip through a TAP 12.

Here, the TAP is a port conforming to the JTAG specification, standardized as “Standard Test Access Port and Boundary-Scan Architecture” in IEEE Standard 1149.1 of the Institute of Electrical and Electronics Engineers, Inc. (IEEE), and a port normally provided in a semiconductor chip. Further, the TAP controller is a device which generates a clock or a control signal in response to a control sequence supplied from the TAP, and is also normally provided in a semiconductor chip.

FIG. 6 shows a configuration of an input section of the deserializer 5 which is connected with the variable delay elements VDL1 and VDL 2. As shown in FIG. 6, the input section is configured such that the data D1 (or the test pattern P1) is given to a data input of the flip-flop FF1 through the variable delay element VDL1, and the high-speed clock CLK2 is given to a clock input of the flip-flop FF1 through the variable delay element VDL2.

FIG. 7 shows in the form of a block diagram a configuration of the variable delay element VDL1. As shown in FIG. 7, the variable delay element VDL1 is configured such that delay elements DL such as buffers or the like having a known delay value are serially connected and an output of each delay element DL is also connected to an input port of a data select element DSL. When the data D1 (or the test pattern P1) is given to an input end of a plurality of serially connected delay elements DL, delay data delayed in accordance with the number of connections of delay elements DL is given from each delay element DL to the data selector DSL.

The data selector DSL selects an output of any one of the delay elements DL by a delay control signal DLC, and the selected output of the delay element DL is outputted as output data of the variable delay element VDL1.

Here, in a case where the delay control signal DLC for example consists of four-bit data, signals of 16 gradations from “0000” to “1111” can be constructed, and may be called VDL codes.

For example, when it is set that delay data having one delay element DL of delay is selected in the case of the delay control signal DLC being “0001”, and delay data having two delay elements DL of delay is selected in the case of the delay control signal DLC being “0010”, it is possible to increase one delay element DL of delay every time the delay control signal DLC is raised by one gradation.

In addition, when it is set that an input port directly connected with data D1 (or the test pattern P1) without the intermediation of the delay element DL is selected in the case of the delay control signal DLC being “0000”, the data D1 can be given to the deserializer 5 without delay at the time of the normal operation, and in the case of delaying the high-speed clock CLK2 at the time of jitter measurement test, the test pattern P1 can be given to the deserializer 5 without delay.

It should be noted that the variable delay element VDL2 has the same configuration, with only replacement of input data by the high-speed clock CLK2.

With the above-mentioned configuration taken into consideration, the jitter measurement test is described.

As described with reference to FIG. 2, at the time of the normal operation, the CDR circuit 6 detects an edge from the data row of the data D1, the high-speed clock CLK2 is generated whose phase is shifted by 90 degrees with the timing of the detected edge taken as a reference, and the data D1 is captured in the deserializer 5 by using the high-speed clock CLK2, whereby the data D1 is captured at the central portion having the largest timing margin.

However, in the jitter measurement test, for example, the phase of the high-speed clock CLK2, having been shifted by 90 degrees, is further shifted by the variable delay element VDL2 in such a direction as to be delayed, and the test pattern P1 is made to be captured in the deserializer 5 by using the delayed high-speed clock CLK2.

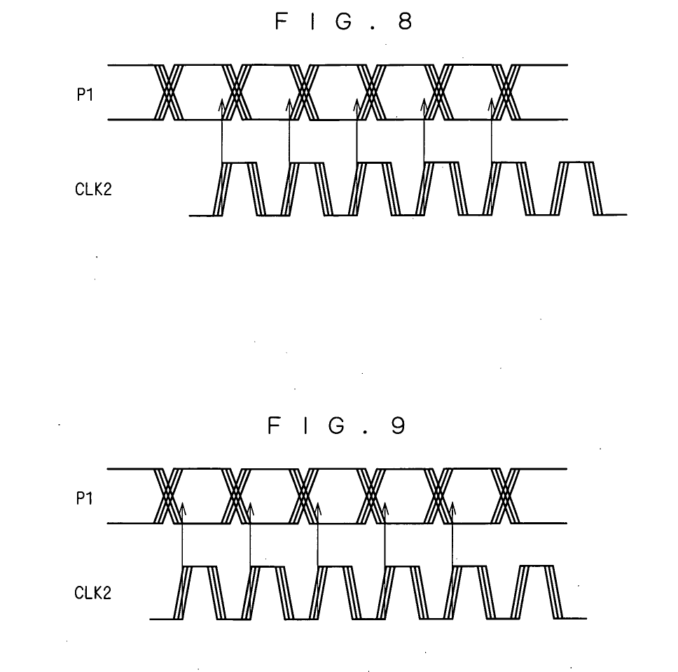

FIG. 8 is a timing chart schematically showing an operation to make the test pattern P1 captured in the deserializer 5 by using the delayed high-speed clock CLK2.

FIG. 8 shows a state where the delayed high-speed clock CLK2 does not capture the central portion out of a jitter region of the test pattern P1, but captures a portion close to the jitter region of the test pattern P1. Since the portion close to the jitter region of the test pattern P1 is captured at an edge having a jitter of the high-speed clock CLK2, it is assumed that a problem may occur in terms of capturing, which may affect the parallel conversion in the deserializer 5. Therefore, the N-bit output data OD takes a pattern different from the test pattern P0 generated in the pattern generation logic 7, namely an error pattern.

Further, in the jitter measurement test, it is possible to shift the test pattern P1 in such a direction as to delay the phase by the variable delay element VDL1, so as to make the test pattern P1 captured in the deserializer 5 by using the high-speed clock CLK2.

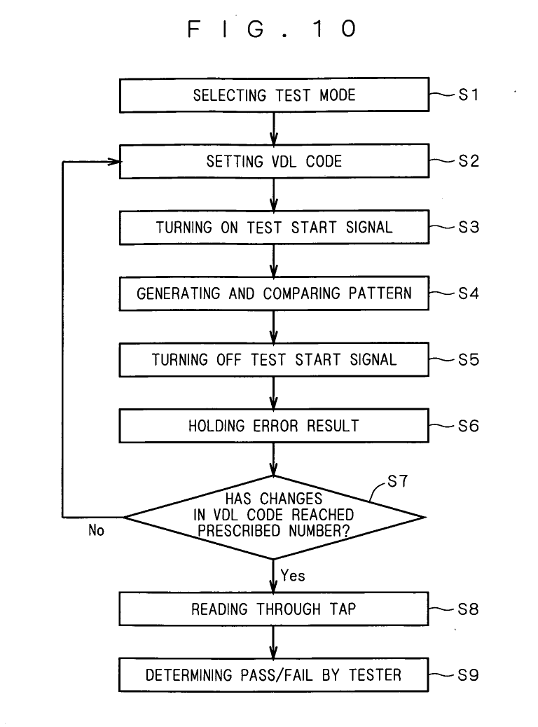

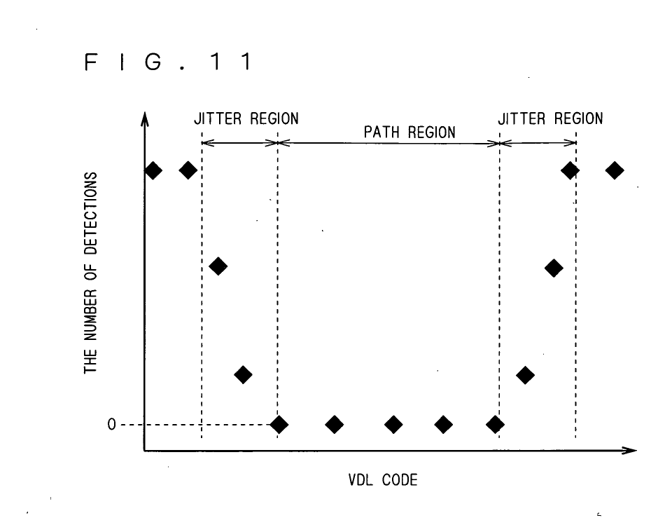

FIG. 9 is a timing chart schematically showing an operation to make the delayed test pattern P1 captured by the high-speed clock CLK2.

FIG. 9 shows a state where the high-speed clock CLK2 does not capture the central portion out of the jitter region of the delayed test pattern P1, but captures the portion close to the jitter region of the test pattern P1. Since the portion close to the jitter region of the test pattern P1 is captured at an edge having a jitter of the high-speed clock CLK2, it is assumed that a problem may occur in terms of capturing, which may affect the parallel conversion in the deserializer 5. Therefore, the N-bit output data OD takes a pattern different from the test pattern P0 generated in the pattern generation logic 7, namely an error pattern.

FIGS. 8 and 9 respectively show the case of drastically delaying the high-speed clock CLK2 and the case of drastically delaying the test pattern P1, but there are some cases where the output data OD does not take an error pattern depending upon the respective delay states.

This delayed state where the error pattern is not generated occurs continuously for a certain period of time, and the period of time can be defined by changing the respective delay times of the high-speed clock CLK2 and the test pattern P1.

The inventor focused attention upon the fact that a path region is varied by the jitters of the high-speed clocks CLK1 and CLK2, and reached a technical idea, of detecting the path region so as to detect jitter characteristics of the PLL circuit 3 and the CDR circuit 6.

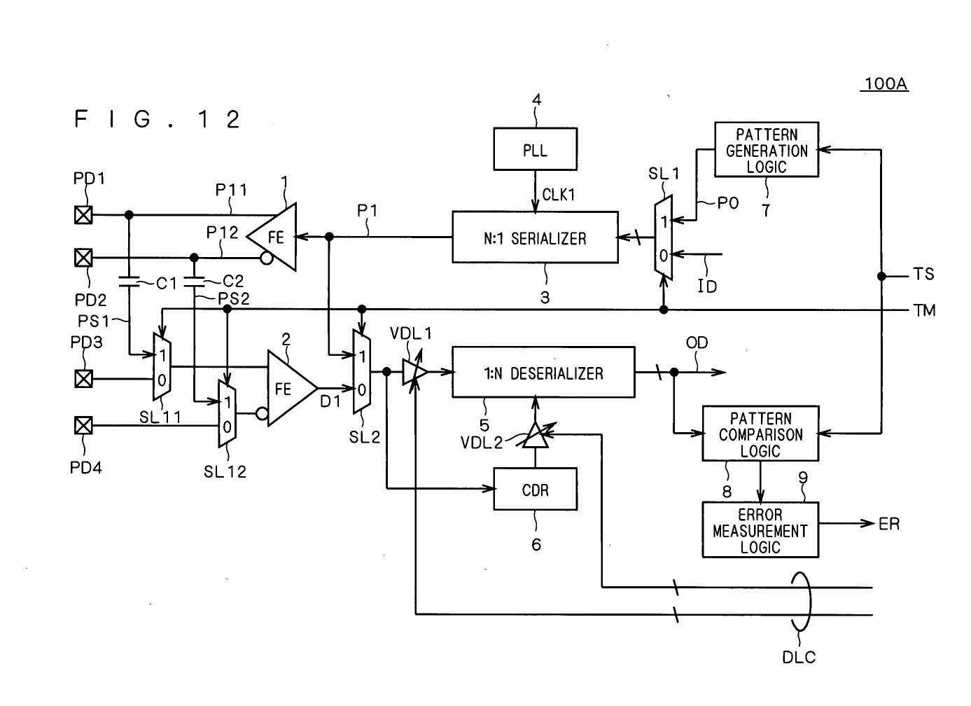

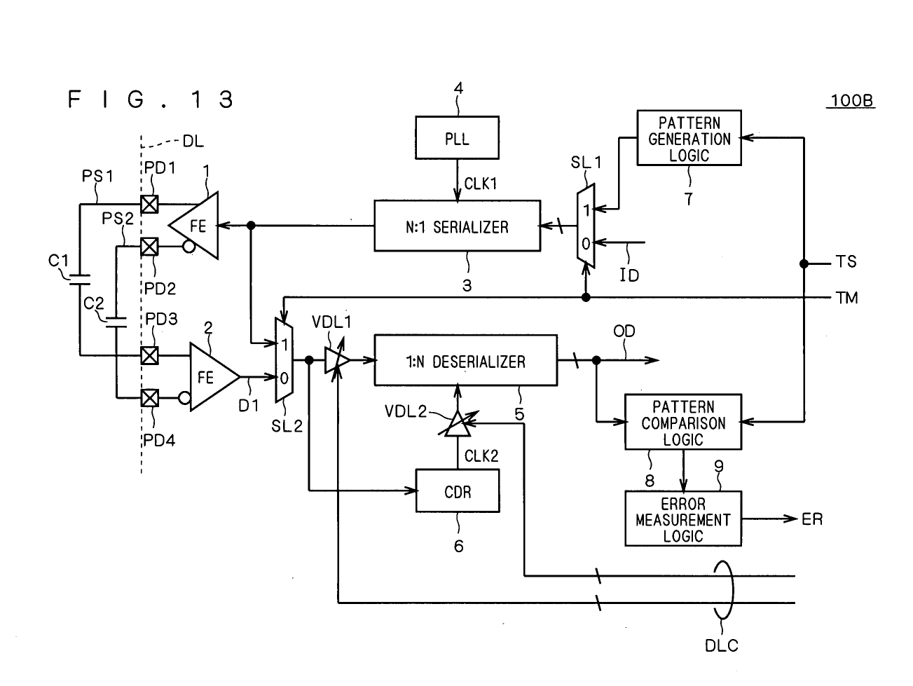

FIG. 10 is a flowchart showing an operation of the jitter measurement test, and FIG. 11 is a view showing the result of the jitter measurement obtained based upon the flow.

In the following, a specific operation of the jitter measurement test is described using FIGS. 10 and 11, with reference to FIG. 5.

As shown in FIG. 10, when a test mode is selected by the test mode selection signal TM from the register group 10 for test control/observation (Step S1), and the delay control signal DLC (VDL code) is set to any of the values (Step S2). In this case, which of the high-speed clock CLK2 and the test pattern P1 is first delayed is also set.

Here, the case of delaying the high-speed clock CLK2 is applied, and the VDL code is set to “0000”.

When the test start signal TS is turned on in Step S3, the N-bit test pattern P0 is outputted from the pattern generation logic 7, and given to the serializer 3 through the selector SL1 to be serial-converted which is then outputted as the test pattern P1.

The test pattern P1 is given to the deserializer 5 and the CDR circuit 6 through the selector SL2, and parallel-converted in the deserializer 5. At this time, the high-speed clock CLK2 with its phase shifted by 90 degrees with respect to the test pattern P1 is generated based upon the test pattern P1 given to the CDR circuit 6.

The high-speed clock CLK2 is given to the variable delay element VDL2, but in the case of VDL code being “0000”, the phase is not delayed and given to the deserializer 5.

Therefore, the phase of the high-speed clock CLK2 is adjusted to a point to which the phase was shifted by 90 degrees with respect to the test pattern P1, which is a point having the largest capture margin, and the parallel-converted N-bit output data OD becomes data almost consistent to the test pattern P0.

The output data OD is given to the pattern comparison logic 8 and compared with the pattern for comparison, but since the pattern for comparison is equivalent to the test pattern P0 generated in the pattern generation logic 7, the output data OD is consistent with the pattern for comparison, and thus determined as the path data.

It is to be noted that the test pattern P0 is outputted from the pattern generation logic 7 during the period of time when the test start signal TS is on, and after the comparing operation is repeated for each waveform of the N-bit output data OD in the pattern comparison logic 8, the test start signal TS is turned off (Step S5).

The results of comparison in the pattern comparison logic 8 are all given to the error measurement logic 9. In the case of the VDL code being “0000”, the number of detections of error data is considered to be zero, and the comparison result information that the number of error detections is “zero” in the case of the VDL code being “0000” is held in the error measurement logic 9 (Step S6). It is to be noted that the number of repetitions of the comparing operations can be arbitrarily set, and is for example set to 1000 to 2000.

Next, in Step S7, it is determined whether or not the number of changes in VDL code has reached a previously set prescribed number, namely, whether or not all the changeable delay times in the variable delay element VDL1 or VDL2 have been applied, and when the number has not reached to the prescribed number, the VDL code is changed by one gradation and set (Step S2), and the operations from Step S3 are repeated.

It is to be noted that, while the VDL code may be changed sequentially by one gradation, the change need not be started with “0000”, and the change may be started with “1111” and finished with “0000”. Or all the changeable delay times in the variable delay element VDL1 or VDL2 may not be applied, and for example, the change may be started with some mid-code and finished with another mid-code. Therefore, the application method is not restricted.

On the other hand, when it is determined that the number of changes in VDL code has reached a predetermined number of times in Step S7, the comparison result information held in the error measurement logic 9 is given to the register group 10 for test control/observation, and outputted from the TAP controller 11 to the outside of the semiconductor chip through the TAP 12, and analysis of the comparison result information is performed using an external tester or the like (not shown).

It is to be noted that, although the number of error detections was “0” in the above since the case of the VDL code being “0000” was described, when the high-speed clock CLK2 is delayed and the point having a low capture margin, i.e. the point close to the jitter region of the test pattern P1, is captured, the output data OD is not consistent with the pattern for comparison as a result of comparison, and the number of detections of error data made in the pattern comparison logic 8 increases.

After the test of delaying the high-speed clock CLK2 has been finished, a test of delaying the test pattern P1 is executed, and its test flow is the same as the flow described with reference to FIG. 10.

FIG. 11 is a view showing the number of error detections with the change in VDL code, obtained by delaying the high-speed clock CLK2 and the test pattern P1 and then analyzing the respectively obtained comparison result information, and summarized in a graph.

In FIG. 11, a region where the number of error detections is defined by a VDL code indicating “0” is taken as the path region, and regions where the number of error detections is defined by a VDL code indicating other than “0” are taken as the jitter regions.

It should be noted that, although the region with the number of error detections being other than “0” is shown as the jitter region in FIG. 11, a threshold for determining the jitter region and the path region can be arbitrarily determined. It can be previously set, or can be changed while the test is performed, and in that case, the threshold may be given as a determination threshold TH from the register group 10 for test control/observation to the error measurement logic 9.

Further, the error measurement logic 9 may not be provided, the information on the comparison result obtained in the pattern comparison logic 8 may be given to the register group 10 for test control/observation, and read to the outside through the TAP 12, and the process, executed by the error measurement logic 9, may be executed by the external tester.

As shown in FIG. 7, the variable delay element VDL1 or VDL2 is configured by using a plurality of delay elements DL having known delay time. For example, when it is configured so as to increase the delay by one delay element DL every time the delay control signal (VDL code) DLC increases by one gradation, an absolute value of the path region, namely a capture region where data can be normally captured, can be obtained by a product of the number of changes in VDL code and one delay element DL of delay time.

When the one delay element DL of delay time is 50 p-sec and the number of changes in VDL code is four, the capture region is 200 p-sec.

When this capture region is shorter than the previously set time, it is possible to determine that jitter characteristics of the PLL circuit 4 and the CDR circuit 6 are problematic, so as to take a measure to exclude a semiconductor chip having such a PLL circuit 4 and such a CDR circuit 6 from objects to be shipped.

### A-3. Effect

As described above, in the high-speed serial transmission input/output section 100 of Embodiment 1, at the time of the jitter measurement test, a data signal is generated in the pattern generation logic 7 built in the TX port TP and given to the serializer 3 and a path is provided for looping an output of the serializer 3 back to the deserializer 5 and the CDR circuit 6, whereby the BIST configuration enabling jitter measurement inside the high-speed serial transmission input/output section 100 is adopted.

This eliminates the need for probing a wafer for measurement in the wafer test, thereby enabling measurement of the jitter characteristic with high accuracy, and reliable detection of a defective product in the wafer test. Therefore, it is possible to prevent a defective product from being packed, so as to reduce assembly cost.

Further, adoption of the BIST configuration allows a closed test to be performed inside the semiconductor chip, thereby eliminating the need for depending upon a measurement system.

That is, since the pattern comparison logic 8 and the error measurement logic 9 are built in the high-speed serial transmission input/output section 100 to detect and determine error data, the tester provided outside just reads the comparison result information as appropriate, and it is thus possible to measure the jitter characteristic without the need for a high-performance tester, so as to prevent an increase in test cost.

Further, it is also possible to measure a jitter characteristic in the state of being mounted on the board after packaging has been performed.

Moreover, since control of the register group 10 for test control/observation and reading of data are performed from the TAP 12 conforming to the JTAG specification through a TAP controller 11, it is not necessary to provide a new input/output pin for performing the jitter measurement test.

It should be noted that the frequency that the TAP 12 can cope with is the order of 10 MHz and the operation is thus slow, but it is fast enough for reading the comparison result information through the TAP 12, and in the BIST configuration built in the high-speed serial transmission input/output section 100, the test is preformed on a signal having a frequency in the GHz order, and its result is read, thereby eliminating the need for the tester coping with a high-speed signal.

Moreover, since the phase changing unit of arbitrarily changing the relative phase relation between the high-speed clock CLK2 and the test pattern P1 is made up of the variable delay element VDL1 and VDL2, the phase changing unit can be easily realized.

### A-4. Modified Example 1

In the high-speed serial transmission input/output section 100, the configuration was shown where the selector SL2 is provided on the inner side than the output buffer 1 and the input buffer 2, namely on the side opposite to the side with the pads PD1 to PD4 provided and the test pattern P1 given to the selector SL2 is given to the variable delay element VDL1 and the CDR circuit 6 through the selector SL2, namely a configuration where the loopback path is provided on the inner side of the output buffer 1 and the input buffer 2.

By providing the loopback path inside the high-speed serial transmission input/output section with a relatively roomy space as thus described, the loopback path can be easily arranged.

However, the configuration of the loopback path is not restricted to this, but a configuration where the loopback path is provided at a front end I/O, namely at the outer side of the output buffer 1 and the input buffer 2 may be adopted.

FIG. 12 shows a configuration of a high-speed serial transmission input/output section 100A where the loopback path is provided between the output buffer 1 and the input buffer 2, and the pads PD3 and PD4. It is to be noted that the same numerals/symbols are provided for the same configuration as that of the high-speed serial transmission input/output section 100 shown in FIG. 4, and an overlapping explanation is eliminated.

As shown in FIG. 12, in the high-speed serial transmission input/output section 100A, the test pattern P1 outputted from the serializer 3 is given to the output buffer 1, and outputted as a differential output. A test pattern P11 outputted from a noninverted output terminal of the output buffer 1 is inputted into the pad PD1 and also inputted into a selector SL11, and a test pattern P12 outputted from an inverted output terminal of the output buffer 1 is inputted into the pad PD2 and also inputted into a selector SL12.

Here, the selectors SL11 and SL12 are switch-controlled by the test mode selection signal TM along with the selector SL1. That is, the selector SL11 is switch-controlled so as to give data, inputted from the outside of the semiconductor chip into the high-speed serial transmission input/output section 100A through the pad PD3, to the noninverted input terminal of the input buffer 2 at the time of the normal operation, and give the test pattern P11 to the noninverted input terminal of the input buffer 2 at the time of the jitter measurement test.

Further, the selector SL12 is switch-controlled so as to give data, inputted from the outside of the semiconductor chip into the high-speed serial transmission input/output section 100A through the pad PD4 at the time of the normal operation, to the inverted input terminal of the input buffer 2, and give the test pattern P12 to the inverted input terminal of the input buffer 2.

It should be noted that a capacitor C1 for capacitive coupling for high-speed signal connection is interposed into a loop path PS1 that gives the test pattern P11 to the selector SL11, and a capacitor C2 for capacitive coupling for high-speed signal connection is interposed into a loop path PS2 that gives the test pattern P12 to the selector SL12.

The test patterns P11 and P12 having been given to the input buffer 2 are given to the variable delay element VDL1 and the CDR circuit 6 as the test pattern P1, and further given to the deserializer 5 through the variable delay element VDL1.

With such a configuration, it is possible to perform measurement of the output buffer 1 and the input buffer 2, which constitute the front end I/O, including measurement of a jitter characteristic, so as to perform a test in a state even closer to an actual use state.

### A-5. Modified Example 2

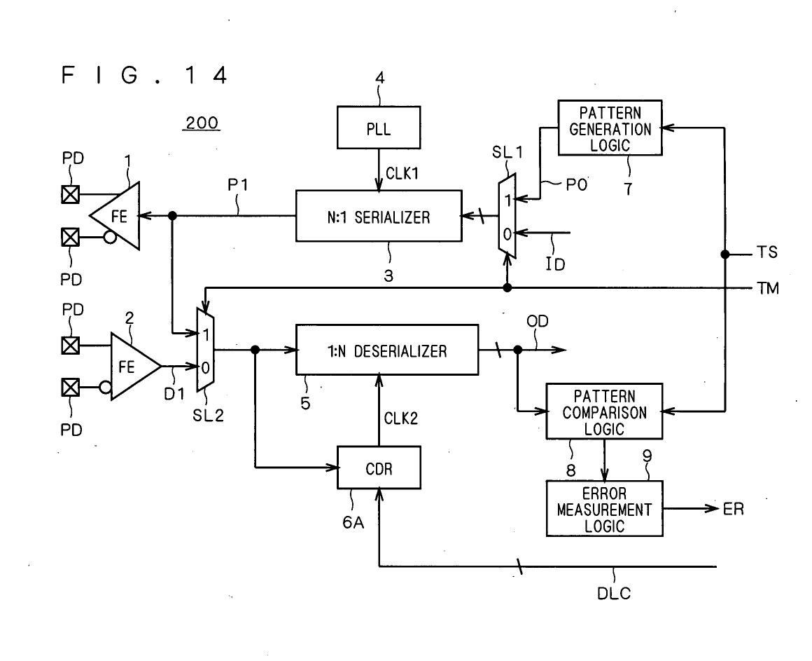

As the configuration where the loopback path is provided at the front end I/O, namely at the outer side of the output buffer 1 and the input buffer 2, as in a high-speed serial transmission input/output section 100B shown in FIG. 13, the loopback path may be provided at the outer side of the arrangement line of the pads PD1 to PD4, namely at the outer side of a wafer dicing line DL. It is to be noted that the same numerals/symbols are provided for the same configuration as that of the high-speed serial transmission input/output section 100 shown in FIG. 4, and an overlapping explanation is eliminated.

A shown in FIG. 13, in the high-speed serial transmission input/output section 100B, the test pattern P1 outputted from the serializer 3 is given to the output buffer 1, and outputted as a differential output. A test pattern P11 outputted from the noninverted output terminal of the output buffer 1 is inputted into the pad PD1, and a test pattern P12 outputted from the inverted output terminal of the output buffer 1 is inputted into the pad PD2. It is configured such that the pad PD1 is connected to the pad PD3 through the loop path PS1 provided at the outer side of the wafer dicing line DL and the pad PD2 is connected to the pad PD4 through the pad PD2 provide at the outer side of the wafer dicing line DL.

It should be noted that the capacitor C1 for capacitive coupling for high-speed signal connection is interposed into the loop path PS1, and the capacitor C2 for capacitive coupling for high-speed signal connection is interposed into the loop path PS2.

Further, the pads PD3 and PD4 are respectively connected to the noninverted input terminal and the inverted input terminal of the input buffer 2, and the test patterns P11 and P12 having been given to the input buffer 2 are given to the variable delay element VDL1 and the CDR circuit 6 as the test pattern P1, and further given to the deserializer 5 through the variable delay element VDL1.

With such a configuration, it is possible to measure the jitter characteristic by using the loop paths PS1 and PS2 at the time of the wafer test.

Moreover, since only the selector SL1 is used as the selector for constituting the loopback path, it is possible to reduce cost generated due to arrangement of a plurality of selectors and eliminate an influence exerted due to the existence of the selector on the path at the time of the normal operation.

It is to be noted that, after the wafer test, the loop paths PS1 and PS2 are separated along the wafer dicing line DL by dicing, where a wafer is cut off into separate semiconductor chips.

### B. Embodiment 2

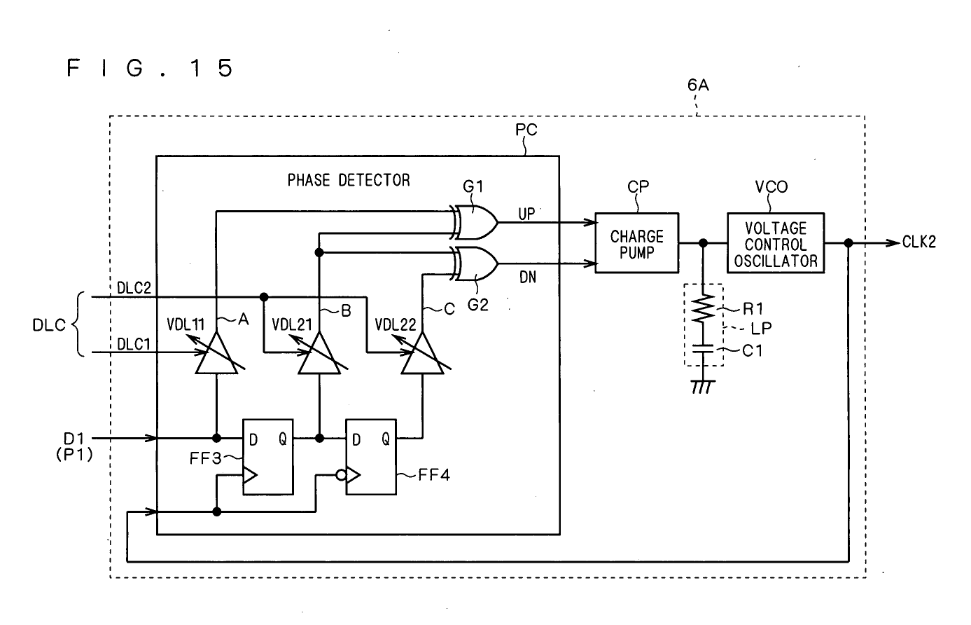

FIG. 14 is a block diagram showing a configuration of a high-speed serial transmission input/output section 200 of Embodiment 2 according to the present invention. It is to be noted that the same numerals/symbols are provided for the same configuration as that of the high-speed serial transmission input/output section 100 shown in FIG. 4, and an overlapping explanation is eliminated.

### B-1. Configuration and Operation of Device

The high-speed serial transmission input/output section 200 shown in FIG. 14 is configured such that the test pattern P1 having been given to the selector SL2 is given to the deserializer 5 and a CDR circuit 6A through the selector SL2.

Upon receipt of the test pattern P1 and the delay control signal DLC, a CDR circuit 6A generates the high-speed clock CLK2, and the high-speed clock CLK2 is given to the deserializer 5, but the CDR circuit 6A also has the function of shifting the phase of the high-speed clock CLK2 by 90 degrees with respect to the test pattern P1 and also delaying the phase of the high-speed clock CLK2.

FIG. 15 shows a block diagram of the configuration of the CDR circuit 6A. As shown in FIG. 15, the CDR circuit 6A is provided with a phase comparator PC, a charge pump CP and a voltage control oscillator VCO, and is configured so as to feed the high-speed clock CLK2, outputted from the voltage control oscillator VCO, back to the phase comparator PC. It is to be noted that a resistance R1 and the capacitor C1 which are serially connected are inserted between the path for connecting an output of the charge pump CP and an input of the voltage control oscillator VCO and a ground potential, to constitute a loop filter LP.

Upon receipt of the test pattern P1 (data D1 at the time of the normal operation) and the delay control signal DLC, the phase comparator PC performs phase comparison between the high-speed clock CLK2 and the test pattern P1, and based upon its result, the phase comparator PC adjusts an up signal UP for extending the phase difference and a down signal DN for reducing the phase difference, and gives the signals to the charge pump CP.

Flip flops FF3 and FF4 which constitute a shift register are provided inside the phase comparator PC, and the high-speed clock CLK2 is given to a clock input of the flip-flop FF3, and also given to an inverted clock input of the flip-flop FF4.

The test pattern P1 is then given to a D-input of the flip-flop FF3, and a Q-output of the flip-flop FF3 is connected to a D-input of the flip-flop FF4.

Moreover, the D-input of the flip-flop FF3 is connected with an input of a variable delay element VDL11 (first variable delay element), and the Q-output of the flip-flop FF3 is connected with an input of a variable delay element VDL21 (second variable delay element). A Q-output of the flip-flop FF4 is connected with an input of a variable delay element VDL22 (third variable delay element).

It is configured such that the delay times for the variable delay element VDL11 is adjusted by a delay control signal DLC1 and the variable delay elements VDL21 and VDL22 are controlled by a common delay signal DLC2.

The variable delay elements VDL11, VDL21 and VDL22 constitute the phase changing unit of arbitrarily changing a relative phase relation between the test pattern P1 and the high-speed clock CLK2.

It is configured such that an output signal A of the variable delay element VDL11 is given to one input of a two-input exclusive OR gate G1, and an output signal B of the variable delay element VDL21 is given to another input of the exclusive OR gate G1.

Further, it is configured such that the output signal B of the variable delay element VDL21 is also given to one input of a two-input exclusive OR gate G2, and an output signal C of the variable delay element VDL22 is given to another input of the exclusive OR gate G2.

An output of the exclusive OR gate G1 is given as the up signal UP to the charge pump CP and an output of the exclusive OR gate G2 is given as the down signal DN to the charge pump CP.

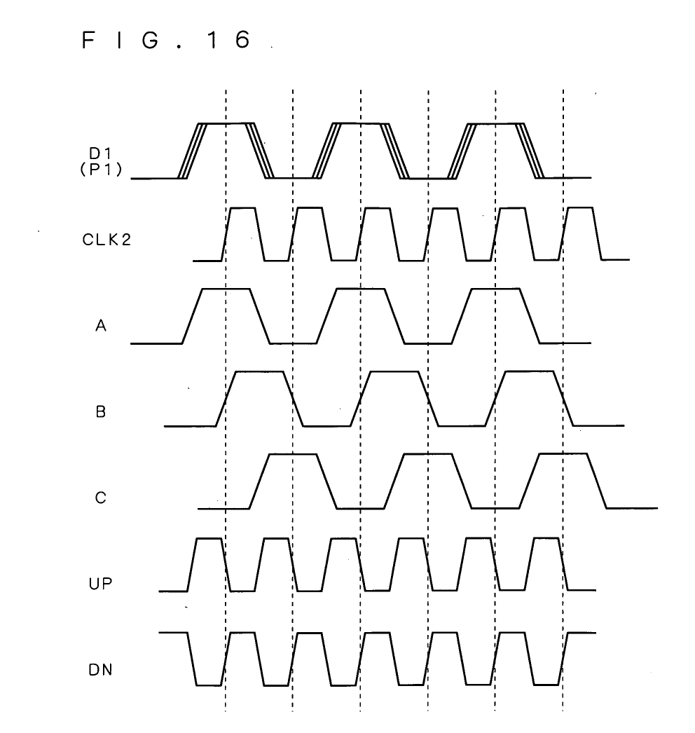

Here, an operation of the phase comparator PC is described with reference to FIGS. 16 to 18. FIG. 16 is a timing chart for explaining an operation to generate the high-speed clock CLK2 with its phase shifted only by 90 degrees with respect to the test pattern P1 in the phase comparator PC.

In this case, the delay control signal DLC1 to be given to the variable delay element VDL11 and the delay control signal DLC2 to be given to the variable delay elements VDL21 and VDL22 are 0 (“0000”), and is thus in the state of not delaying the variable delay elements VDL11, VDL21 and VDL22. The respective output signals B and C of the variable delay elements VDL21 and VDL22 in this state each have a waveform with its phase shifted by 90 degrees with respect to the output signal A of the variable delay element VDL21. The up signal UP is generated by an exclusive OR of each of the output signals A and B, and the down signal DN is generated by an exclusive OR of each of the output signals B and C.

That is, when the phase difference between the high-speed clock CLK2 and the test pattern P1 is not smaller than 90 degrees, a zone with the up signal UP in a high state is extended.

Upon receipt of this result, in the charge pump CP, a voltage to be inputted into the voltage control oscillator VCO is adjusted in accordance with the length of the high-state zone of the up signal UP. In the voltage control oscillator VCO, a frequency of the high-speed clock CLK2 is once increased in accordance with an input voltage from the charge pump CP. Thereby, the phase of the high-speed clock CLK2 to be fed back is advanced, and the phase difference from the test pattern P1 becomes closer to 90 degrees.

Conversely, when the phase difference between the high-speed clock CLK2 and the test pattern P1 is smaller than 90 degrees, the high-state zone of the down signal DN is extended.

Upon receipt of this result, in the charge pump CP, a voltage to be inputted into the voltage control oscillator VCO is adjusted in accordance with the length of the high-state zone of the down signal DN. In the voltage control oscillator VCO, a frequency of the high-speed clock CLK2 is once decreased in accordance with an input voltage from the charge pump CP. Thereby, the phase of the high-speed clock CLK2 to be fed back is delayed, and the phase difference from the test pattern P1 becomes closer to 90 degrees.

Finally, at the time point when the phase difference between the high-speed clock CLK2 and the test pattern P1 becomes 90 degrees, the high-state zone of the up signal UP becomes as high as the high-state zone of the down signal DN, and the phase and frequency are stabilized at those of the high-speed clock CLK2 outputted by the voltage control oscillator VCO at that time point.

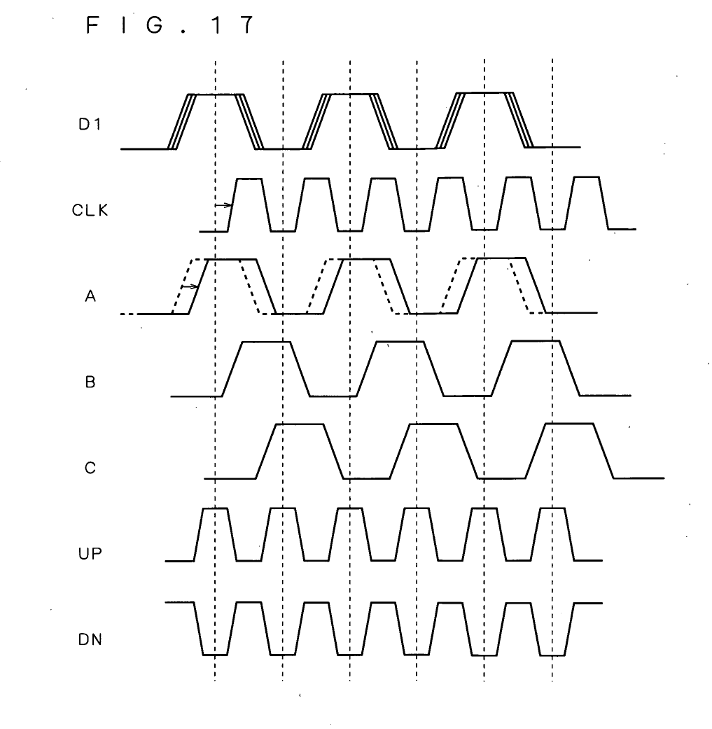

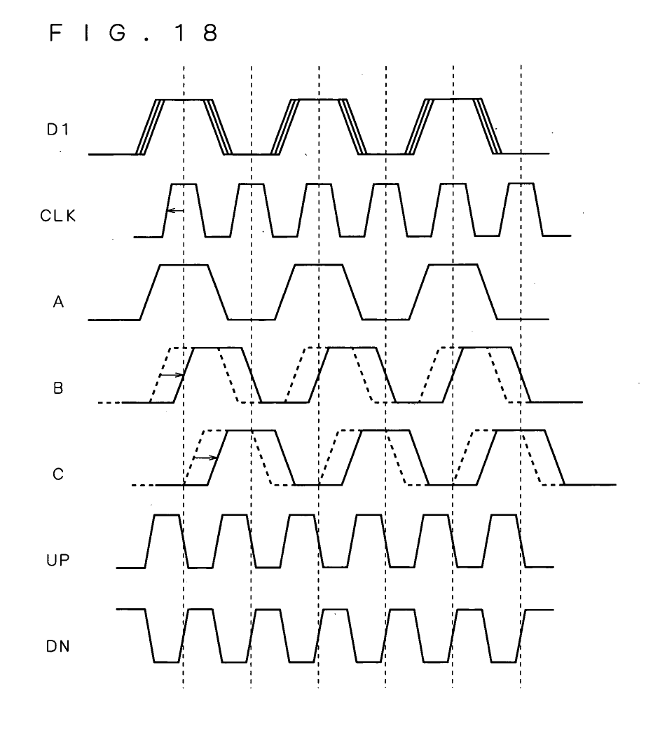

FIG. 17 is a timing chart for explaining an operation to further delay the phase of the high-speed clock CLK2 which has been shifted by 90 degrees with respect to the test pattern P1.

In this case, the delay control signal DLC1 (VDL code) to be given to the variable delay element VDL11 is incremented to give a desired delay to the output signal A for offset.

With this offset, the high-state zone of the down signal DN is extended, an input voltage from the charge pump CP is changed, and the frequency of the high-speed clock CLK2 outputted from the voltage control oscillator VCO is changed. However, since the delay due to the offset is finally compensated, the phase of the high-speed clock CLK2 is stable at the point where the phase is composed of the phase shifted by 90 degrees from the test pattern P1 and the delay due to the offset. FIG. 17 is a timing chart in a stable state, and the up signal UP and the down signal DN are also stable as symmetric signals.

FIG. 18 is a timing chart for explaining an operation to advance the phase of the high-speed clock CLK2 which has been shifted by 90 degrees with respect to the test pattern P1.

In this case, the delay control signal DLC2 (VDL code) to be given to the variable delay elements VDL21 and VDL22 is incremented to give a desired delay to the output signals B and C, and then offset.

With this offset, the high-state zone of the up signal UP is extended, and an input voltage from the charge pump CP is changed, leading to a change in frequency of the high-speed clock CLK2 outputted from the voltage control oscillator VCO. Since the offset is to be compensated, ultimately, the phase of the high-speed clock CLK2 becomes stable at a point of (90-degree shift from the test pattern P1)−(offset delay). FIG. 18 is a timing chart in a stable state, where the up signal UP and the down signal DN are also stable as symmetric signals.

As thus described, in the CDR circuit 6A, the variable delay elements VDL11, VDL21 and VDL22 are built the phase comparator PC and the delay control signal DLC to be given to these elements can be adjusted to advance or delay the phase of the high-speed clock CLK2 so that the jitter measurement which was described with reference to FIG. 11 can be obtained, as in the case of the high-speed serial transmission input/output section 100 described in Embodiment 1.

### B-2. Effect

In the high-speed serial transmission input/output section 200 of Embodiment 2, since the BIST configuration enabling the jitter measurement has been adopted as in the high-speed serial transmission input/output section 100 described in Embodiment 1, it goes without saying that the same effect as that of the high-speed serial transmission input/output section 100 is exerted, and the configuration has been adopted where the variable delay elements VDL11, VDL21 and VDL22 are built into the CDR circuit 6A, to make only the phase of the high-speed clock CLK2 variable.

Therefore, at the time of the normal operation, the data D1 does not pass along the path including the variable delay element, thereby preventing the data D1 from being affected by passage through the variable delay element.

Moreover, since the data D1 passes along the same path at the time of the normal operation and at the time of jitter measurement test, the test at the time of jitter measurement test can be performed on the same conditions as those at the time of the normal operation, and it is thereby possible to perform measurement further closer to an actual operation, so that improvement in measurement accuracy can be expected.

### B-3. Modified Example

It is to be noted that also in the high-speed serial transmission input/output section 200 of the present embodiment, as in the high-speed serial transmission input/output section 100A described with reference to FIG. 12, the configuration where the loopback path is provided at the front end I/O, namely at the outer side of the output buffer 1 and the input buffer 2, may be adopted.

Further, as in the high-speed serial transmission input/output section 100B described with reference to FIG. 13, the loopback path may be provided at the outer side of the arrangement line of the pads PD1 to PD4, namely at the outer side of the wafer dicing line DL.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising a serial transmission input/output section having:
a first clock generating section for generating a first clock;
a serializer for serial-converting parallel data based upon a timing of said first clock;
a second clock generating section for generating a second clock.
a deserializer for converting serial data into parallel one based upon a timing of said second clock;
a pattern generating section for generating a first pattern as said parallel data;
a loopback path for giving a second pattern, outputted by said serializer having received said first pattern, to said deserializer;
a pattern comparing section for performing pattern comparison between output data outputted by said deserializer having received said second pattern and a pattern for comparison; and
a phase changing unit of arbitrarily changing a relative phase relation between said second pattern and said second clock,
wherein the pattern comparison is performed between said output data and said pattern for comparison in said pattern comparing section every time said relative phase relation is changed by said phase changing unit, and in a case where the two patterns are inconsistent, the data is determined as error data.

2. The semiconductor device according to claim 1, wherein
said serial transmission input/output section further has an error measuring section for receiving said error data outputted from said pattern comparing section to measure the number of detections of said error data with respect to each of said relative phase relations, and
said error measuring section outputs to the outside information on the number of detections of said error data with respect to each of said relative phase relations.

3. The semiconductor device according to claim 1, wherein
said phase changing unit includes:
a first variable delay element interposed into a channel for giving said second pattern to said deserializer; and
a second variable delay element interposed into a channel for giving said second clock to said deserializer,
changes a phase of said second pattern by said first variable delay element in such a direction as to be delayed from said second clock, and
changes a phase of said second clock by said second variable delay element in such a direction as to be delayed from said second pattern, to change said relative phase relations.

4. The semiconductor device according to claim 1, wherein
said second clock generating section receives said second pattern, to reproduce and output said first clock as said second clock, and
said phase changing unit is built in said second clock generating section, and changes a phase of said second clock in such a direction as to be delayed or advanced from said second pattern, to change said relative phase relation.

5. The semiconductor device according to claim 3, wherein
said second clock generating section has:
a first flip-flop for receiving said second pattern, to output a first signal so as to delay its phase by 90 degrees;
a second flip-flop for receiving said first pattern, to output a second signal so as to delay its phase by 90 degrees;
a first logic gate for receiving said second pattern and said first signal, to conduct logic calculation;
a second logic gate for receiving said first and second signals, to perform logic calculation; and
an oscillator for adjusting a frequency based upon output signals of said first and second logic gates, to output said second clock,
said second clock is fed back to clock inputs of said first and second flip-flops,
said phase changing unit includes:
a first variable delay element, which is interposed into a channel for giving said second pattern to said first logic gate, and delays said second pattern to be outputted as a first delay signal;
a second variable delay element, which is interposed into a channel for giving said first signal to said first and second logic gates, and delays said first signal to be outputted as a second delay signal; and
a third variable delay element, which is interposed into a channel for giving said second signal to said second logic gate, and delays said second signal to be outputted as a third delay signal,
changes a phase of said first delay signal by said first variable delay element in such a direction as to be delayed from said second clock, to change a phase of said second clock in such a direction as to be delayed from said second pattern, and
changes phases of said first and second delay signals by said second and third variable delay elements in such a direction as to be delayed from said second clock, to change the phase of said second clock in a direction so as to be advanced from said second pattern.

6. The semiconductor device according to claim 1, wherein
said serial transmission input/output section has:
an output section for outputting an output of said serializer to the outside; and
an input section for inputting data from the outside, and
said loopback path is provided at the inner side of said output section and said input section.

7. The semiconductor device according to claim 1, wherein
said serial transmission input/output section has:
an output section for outputting an output of said serializer to the outside;
an input section for inputting data from the outside;
a first terminal section for receiving an output from said output section; and
a second terminal section for receiving said data to be inputted into said input section, and
said loopback path is provided between arrangements of said output section and said input section, and said first and second terminal sections.
